(19) United States
(12) Patent Application Publication
(10) Pub. No.: US 2007/0114674 A1
(43) Pub. Date: May 24, 2007

(54) Hybrid solder pad

(76) Inventor: Matthew R. Brown, Gurnee, IL (US)

Correspondence Address: MOTOROLA INC, 600 NORTH US HIGHWAY 45, ROOM AS437, LIBERTYVILLE, IL, 60048-5343, US

(21) Appl. No.: 11/285,001

(22) Filed: Nov. 22, 2005

(51) Int. Cl. H01L 23/48

(52) U.S. Cl. 257/780

(57) ABSTRACT

Disclosed herein is a solder pad interface for a solder joint on a substrate.

The solder pad interface includes a soldermask defined (SMD) interface between a solder pad (202) and the substrate, and a non-soldermask defined (NSMD) interface between the solder pad and the solder joint. The SMD interface can include a layer of insulating material (208) configured as an overlaid stencil with apertures through which the NSMD interface of the solder pad is substantially accessible. The SMD interface can include a soldermask (210) configured to cover an outer portion (212) of the solder pad. The NSMD interface includes a raised central portion (214) of the solder pad having a top. The layer of insulating material can be substantially flush with the top of the raised central portion. The raised central portion can provide the NSMD interface between the solder pad and the solder joint.

### FIELD

The present disclosure relates to electronic fabrication technology, and more particularly to a solder pad for component mounting on a substrate.

### BACKGROUND

Many current electronic devices are compact in construction, affording a multitude of components within the device housing to support a wide variety of features. Such devices include handheld consumer electronic devices, such as cellular telephones and digital still and video cameras. Much, if not all, of present-day construction employs surface mount technology for electronic component placement, support, and interconnection. Integrated circuits, surface mount capacitors, and other components are available in packages designed for placement on a substrate such as a printed circuit board (PCB) using surface mount technology.

Typically a PCB is a laminate including layers of insulative material, such as resin, on which may be deposited conductive traces. An insulative layer may be applied as the final layer of the PCB or other substrate. The final, insulative, layer may be referred to as a soldermask. Apertures in the soldermask provide access to conductive pads, referred to herein as terminal pads, for connecting component leads. A terminal pad when configured for receiving a solder joint, as described below, may be referred to herein as a solder pad.

Handheld consumer electronic devices, for example, cellular radiotelephones, may include components such as integrated circuits with many leads, that is, with high lead or high pin counts. PCBs may be fabricated to include arrays of terminal pads to facilitate mounting the high lead count components.

Two varieties of solder pads may be generally found on a PCB. In a soldermask defined (SMD) solder pad, a flat terminal pad is formed on the PCB prior to applying the soldermask layer. An aperture formed in the soldermask exposes a portion of the terminal pad to define the area over which solder can flow during a reflow or baking process to form a solder bond between the component lead and the terminal pad.

In a non-soldermask defined (NSMD) solder pad, on the other hand, the aperture formed in the soldermask exposes the entire terminal pad and a portion of the surrounding substrate that would otherwise underlie the soldermask. In a NSMD solder pad, the terminal pad defines the area over which solder can flow during reflow or baking to form a solder bond between the component lead and the terminal pad. For either variety, SMD or NSMD, the solder pads may be circular, oval, rectangular, or may also be made of other shapes. In both the SMD and NSMD pads, the solder joints, when subjected to stress, may form cracks and suffer failure.

FIG. 1A shows at 100 a side cross-sectional view of a solder ball 102 on a conventional SMD solder pad 104 after reflow or baking. FIG. 1A also shows a trace 106, part of which underlies the solder pad 104. As shown, part of the trace is covered by an insulative layer 108 in which the trace and solder pad may also be embedded as shown. A topmost insulative layer in FIG. 1A serves as a soldermask 110.

A SMD solder pad may provide resistance against pull-out of the terminal pad away from the substrate since the soldermask covers a portion of the terminal pad. However, stresses can concentrate near the neck 112 at the base of the solder ball connection to the solder pad 104. The concentrated stresses at the neck can lead to an onset of failure through development of cracks near the neck.

FIG. 1B shows at 120 a side cross-sectional view of a solder ball 122 on a conventional NSMD solder pad 124 after reflow or baking. FIG. 1B also shows a trace 126, part of which underlies the solder pad 124. The trace and solder pad may be embedded in insulative material 128. A topmost insulative layer in FIG. 1B serves as a soldermask 130. It will be noted that no part of the soldermask covers any part of the solder pad 124.

Because the solder of the solder ball 122 may adhere to the sides of the solder pad as well as to the top, stresses may be better distributed and thus development of cracks in the solder joint under conditions of stress may be forestalled. However, because the solder pad is exposed, with no portion covered by the soldermask, a NSMD solder pad can be prone under stress to a failure mode in which the terminal pad separates from the substrate.

It has been noted that solder joints made with lead-free solders may be more prone to failure when subjected to high strain rates than solder joints containing lead. However, new standards for hazardous wastes in electronic components, e.g., RoHS compliance, have prompted a move away from the use of tin-lead (SnPb) solders to tin-silver-copper (SnAgCu) solders. Accordingly, a solder pad with better performance under high strain rates would be desirable.

### BRIEF DESCRIPTION OF THE DRAWINGS

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1A shows a side cross-sectional view of a conventional soldermask defined (SMD) solder pad;

FIG. 1B shows a side cross-sectional view of a conventional non-soldermask defined (NSMD) solder pad;

FIG. 2 shows a side cross-sectional view of a hybrid solder pad according to an embodiment as described herein;

FIG. 3 shows schematically a top view of the hybrid solder pad of FIG. 2; and

FIG. 4 shows a flow chart for a method according to an embodiment as described herein.

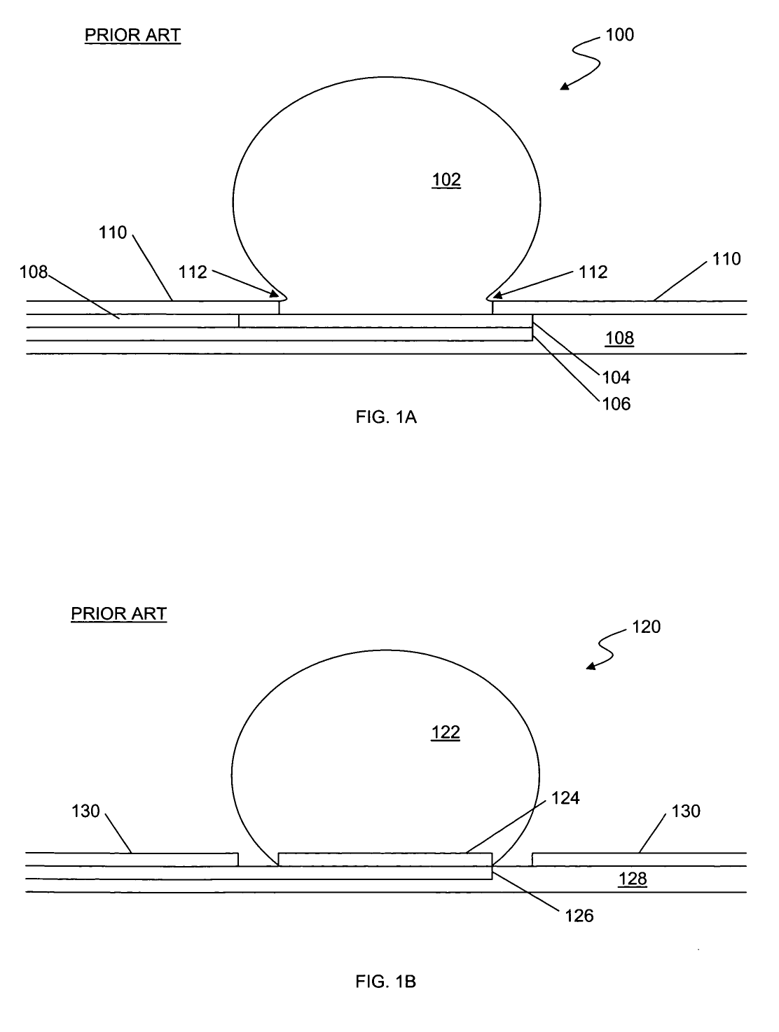

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Disclosed herein is a solder pad interface for a solder joint on a substrate. The solder pad interface includes a SMD interface between a solder pad and the substrate, and a NSMD interface between the solder pad and the solder joint. The solder pad is a hybrid of a SMD and a NSMD solder pad. That is, the solder pad is a combination of a SMD solder pad and a NSMD solder pad. The topmost insulative layer of the PCB or other substrate overhangs the brim of the top hat shaped solder pad, but does not completely cover the brim. Therefore, an applied solder ball has two surfaces with which to bond, the side and the top of the top hat.

The two surfaces can be substantially perpendicular to each other and therefore may be less likely to form a crack than when solder bonds to a single surface. Moreover, the two surfaces can be convex with respect toward the centroid of the solder ball and therefore solder bonding to the two surfaces can be less likely to form a crack than when the bonding surface of the solder pad is flat or concave toward the centroid of the solder ball. The solder bond with the hybrid SMD and NSMD solder pad can create added strength in the bond of the circuit component to the substrate through the solder pad.

The instant disclosure is provided to further explain in an enabling fashion the best modes of making and using various embodiments in accordance with the present invention. The disclosure is further offered to enhance an understanding and appreciation for the invention principles and advantages thereof, rather than to limit in any manner the invention. The invention is defined solely by the appended claims including any amendments of this application and all equivalents of those claims as issued.

It is further understood that the use of relational terms, if any, such as first and second, top and bottom, and the like are used solely to distinguish one from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element preceded by “comprises . . . a” does not, without more constraints, preclude the existence of additional identical elements in the process, method, article, or apparatus that comprises the element.

Much of the inventive functionality and many of the inventive principles are best implemented with or in software programs or instructions and integrated circuits (ICs) such as application specific ICs. It is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation. Therefore, in the interest of brevity and minimization of any risk of obscuring the principles and concepts according to the present invention, further discussion of such software and ICs, if any, will be limited to the essentials with respect to the principles and concepts within the preferred embodiments.

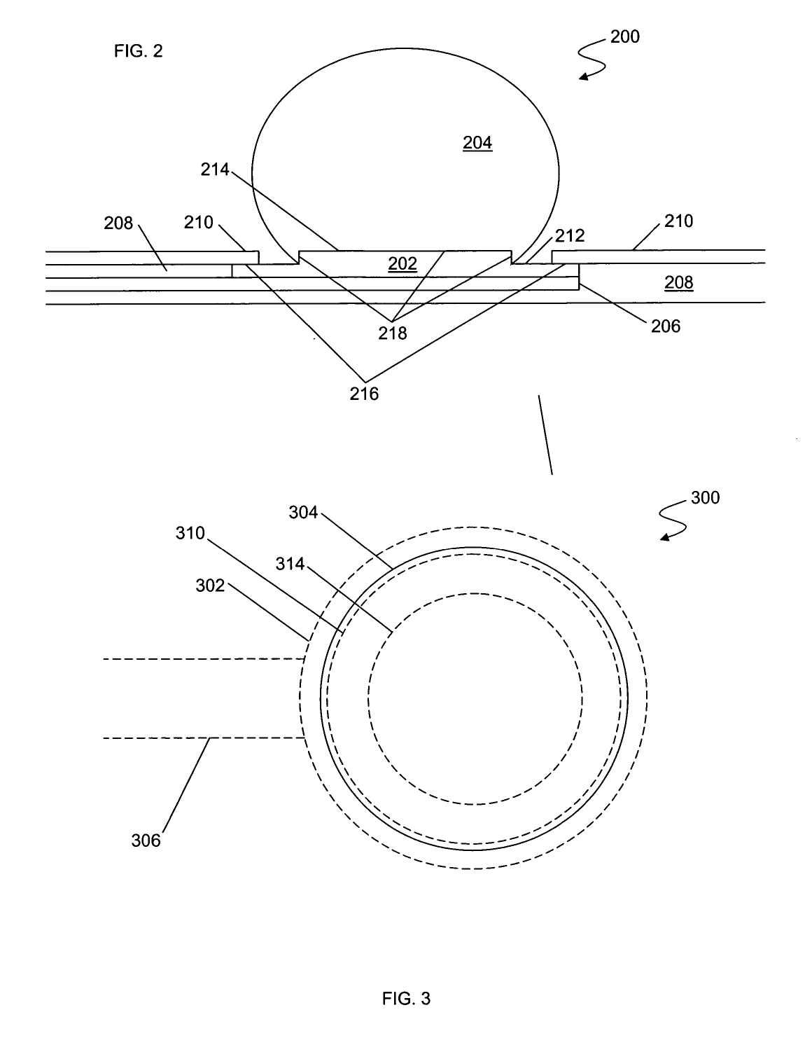

FIG. 2 shows at 200 a side cross-sectional view of a hybrid solder pad 202 according to an embodiment as described herein. The solder pad 202 is a hybrid solder pad in that features of both a SMD solder pad and a NSMD solder pad are combined in the hybrid solder pad 202 of the present disclosure. Also shown in FIG. 2 is a solder ball 204 atop the pad after reflow or baking. A conductive trace 206 underlies and makes electrical contact with the solder pad 202. As shown, part of the trace 206 is covered by an insulative layer 208 in which the trace and solder pad may also be embedded as shown. A topmost insulative layer in FIG. 2 serves as a soldermask 210.

Hybrid solder pad 202 has an appearance somewhat like a top hat, with a lower, flat outer portion 212 (the “brim”) and a raised central portion 214. The soldermask 210 covers an outer portion or edge of the hybrid solder pad 202 as shown, forming a SMD interface 216. This can strengthen the hybrid solder pad 202 against pull out from the PCB under conditions of stress. The soldermask 210 may be configured as an overlaid stencil with an aperture through which a NSMD interface 218 of the solder pad is substantially accessible. The surface of soldermask 210 may be substantially flush with the top of the raised central portion 214.

The raised central portion 214 (the top of the top hat) along with the sides of the raised central portion provide the NSMD interface 218. It will be noted that the NSMD interface may include a gap between raised central portion 214 and the soldermask 210. As shown in FIG. 2, the solder ball 204 can adhere to the sides of the raised central portion as well as to its top 214, and may provide better resistance against formation of cracks, fractures, or other causes of solder joint failure under conditions of stress. It should also be noted that the solder ball 204 may also adhere to the NSMD interface gap particularly as a result of the reflow process and the wetting action of the solder.

FIG. 3 shows at 300 a schematic top view of the hybrid solder pad of FIG. 2. In FIG. 3, boundaries of the features discussed with reference to FIG. 2 are shown. The outermost boundary of hybrid solder pad 202 is shown as a dashed circle at 302. Although solder pad 202, and other features discussed in connection with FIG. 3, are shown as circular, it is understood that other shapes may be possible, including, but not limited to, square, rectangular, or oval. An outline of solder ball 204 is shown at 304.

As discussed above, a conductive trace makes contact with hybrid solder pad 202. The trace is shown schematically in top view in FIG. 3 at 306. Portions of the trace underlying hybrid solder pad 202 are not shown in FIG. 3. An aperture in soldermask 210 is shown in outline at 310. As previously discussed, soldermask 210 overlies an outer portion or edge of hybrid solder pad 202, as shown in FIG. 3 at 302, to strengthen the solder pad against pull out. The edge of raised central portion 214 of FIG. 2 is shown at 314. Although the trace 206 is shown in this exemplary embodiment as underlying the hybrid solder pad 202, it is understood, and known to one of ordinary skill in the art, that the solder pad may be an extension of the trace and therefore in the same plane as the trace.

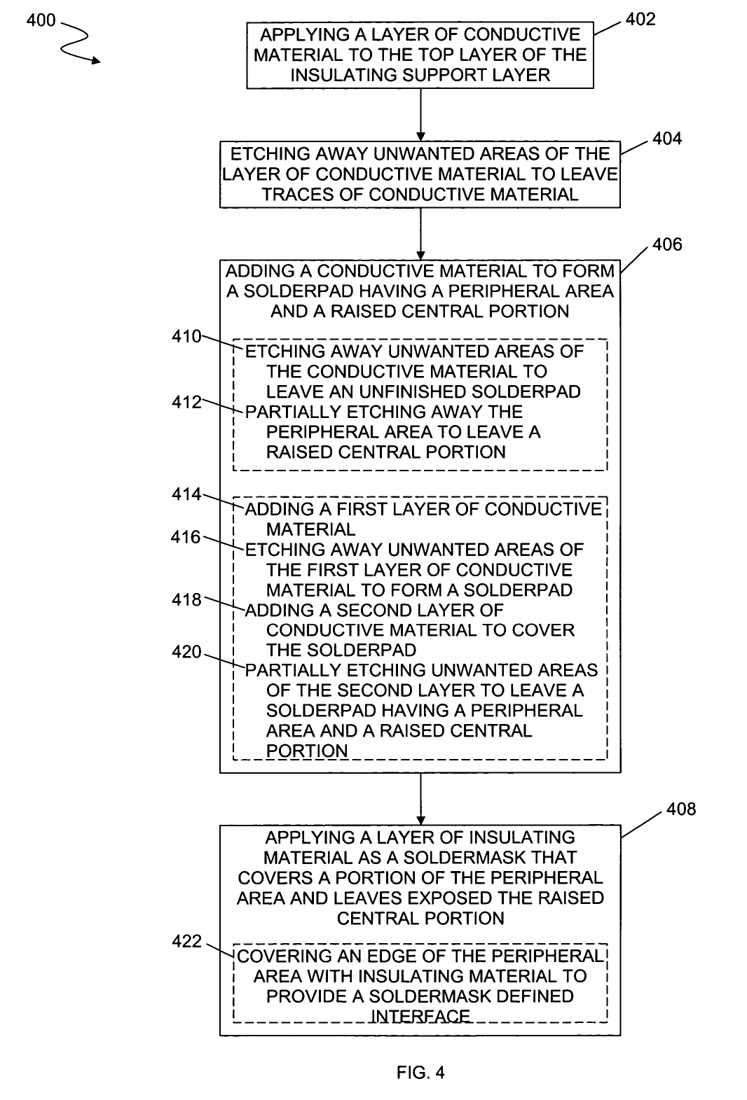

FIG. 4 shows a flow chart 400 for a method according to an embodiment as described herein. It will be understood that the method can be practiced in the course of PCB fabrication. Accordingly, some steps of conventional PCB fabrication are not discussed in detail here. For example, a PCB can typically have several layers with conductive traces separated with layers of insulative material. In addition, vias and anchors can be features of a PCB. Techniques for their formation on a PCB are not discussed herein. For purposes of this discussion, the substrate can be understood to have an insulating support layer with a top surface, to which the steps described below may be applied.

A step of applying a layer of conductive material to the top layer of the insulating support layer is shown at 402. Traces of conductive material may be left on the top surface of the insulating support layer by etching away unwanted areas of the layer of conductive material 404 applied in step 402.

Etching is a process to remove sections of unwanted copper, leaving just the copper that will be used as the traces (i.e. circuit). A layer of conductive material, for example, copper, is deposited on or applied to the PCB. Next, a layer of photo-resist material is applied. The photo-resist material may protect the copper underlying it from the subsequent etching step. The photo-resist material may also resist removal by particular chemicals. However, the photo-resist material may become chemically removable upon curing, that is, upon sufficient exposure to ultraviolet (UV) light. A UV light may be used to cure the areas of photo resist. A positive UV translucent artwork film of the circuit trace layout pattern is made. The artwork film is opaque in areas where a circuit trace is to remain, and is clear in areas where copper is to be etched away. After the film is made it is placed on the PCB and is exposed to the UV light. The exposure cures the areas of the photo-resist corresponding to areas where copper is to be etched away. In an area where a circuit trace is to remain, the opacity of the film covering that area prevents curing of the photo-resist by the UV light. The PCB may then be placed into a developer bath that can develop and remove the sensitized (i.e., cured) photo-resist. The resist that is left is in the shape of the artwork that represents the circuit traces. The board may then be placed in a bath to remove the exposed areas of copper (etch away the copper), and leave the circuit traces on the board. It is understood that other techniques for forming the circuit may be employed. For example, additive copper plating may be used to form the circuit traces and solder pads.

A step 406 of adding a conductive material to form a solder pad having a peripheral area and a raised central portion is shown. The step 406 may be carried out in different ways, as will be discussed further below. Following step 406, a step 408 of applying a layer of insulating material as a soldermask that covers a portion of the peripheral area and leaves exposed the raised central portion is shown.

In a particular embodiment of the method, the step 406 may include a step 410 of etching away unwanted areas of the conductive material to leave an unfinished solder pad having a peripheral area. Step 406 may also include a step 412 of partially etching away the peripheral area of the unfinished solder pad to leave a solder pad having a raised central portion.

In another embodiment the step 406 may include adding a first layer of conductive material 414. The step 406 may in addition include etching away unwanted areas of the first layer of conductive material to form a solder pad 416. A step 418 of adding a second layer of conductive material to cover the solder pad may be included. Shown at 420 is a step of etching away unwanted areas of the second layer to leave a solder pad having a peripheral area and a raised central portion.

In still another embodiment, the step 408 or applying a layer of insulating material as a soldermask may include covering an edge of the peripheral area of the solder pad with insulating material to provide a SMD interface between the solder pad and the substrate 422.

Embodiments of the method may be used in fabrication of substrates for mounting of electronic components, as previously discussed. Such substrates may include, but are not limited to, PCBs and integrated circuit chips. The substrates may be used in electronic devices, such as cellular telephones and other wireless devices.

As described herein, a hybrid solder pad may better resist stresses which in a conventional SMD solder pad may lead to solder joint failure through cracking or other fracture of the solder joint, and which in a conventional NSMD solder pad may lead to pull out of the solder pad from the substrate. Several embodiments of a method for fabricating a hybrid solder pad have also been described.

This disclosure is intended to explain how to fashion and use various embodiments in accordance with the technology rather than to limit the true, intended, and fair scope and spirit thereof. The foregoing description is not intended to be exhaustive or to be limited to the precise forms disclosed. Modifications or variations are possible in light of the above teachings. The embodiment(s) was chosen and described to provide the best illustration of the principle of the described technology and its practical application, and to enable one of ordinary skill in the art to utilize the technology in various embodiments and with various modifications as are suited to the particular use contemplated. All such modifications and variations are within the scope of the invention as determined by the appended claims, as may be amended during the pendency of this application for patent, and all equivalents thereof, when interpreted in accordance with the breadth to which they are fairly, legally and equitable entitled.

1. A method in a substrate having an insulating support layer with a top surface, the method comprising:
applying a layer of conductive material to the top surface of the insulating support layer;
etching away unwanted areas of the layer of conductive material to leave traces of conductive material on the top surface of the insulating support layer;
adding a conductive material to form a solder pad having a peripheral area and a raised central portion; and
applying a layer of insulating material as a soldermask that covers a portion of the peripheral area and leaves exposed the raised central portion.

2. The method of claim 1, wherein applying a layer of insulating material comprises:
covering an edge of the peripheral area of the solder pad with insulating material to provide a soldermask defined interface between the solder pad and the substrate.

3. The method of claim 1, wherein adding a conductive material to form a solder pad comprises:
etching away unwanted areas of the conductive material to leave an unfinished solder pad having a peripheral area; and
partially etching away the peripheral area of the unfinished solder pad to leave a solder pad having a raised central portion.

4. The method of claim 1, wherein adding a conductive material to form a solder pad comprises:
adding a first layer of conductive material;
etching away unwanted areas of the first layer of conductive material to form a solder pad;
adding a second layer of conductive material to cover the solder pad; and
etching away unwanted areas of the second layer to leave a solder pad having a peripheral area and a raised central portion.

5. The method of claim 1, wherein the substrate is an integrated circuit chip.

6. The method of claim 1, wherein the substrate is a printed circuit board.

7. A solder pad interface for a solder joint on a substrate, the solder pad interface comprising:
a soldermask defined interface between a solder pad and the substrate,
wherein the solder pad has a lower flat outer portion and a raised central portion; and
a non-soldermask defined interface between the solder pad and the solder joint.

8. The solder pad interface of claim 7, wherein the soldermask defined interface comprises:
a layer of insulating material configured as an overlaid stencil with an aperture through which the non-soldermask defined interface of the solder pad is substantially accessible.

9. The solder pad interface of claim 7, wherein the soldermask defined interface comprises a soldermask configured to cover the outer portion of the solder pad.

10. The solder pad interface of claim 7, wherein the non-soldermask defined interface comprises the raised central portion of the solder pad having a top, and wherein the layer of insulating material is substantially flush with the top of the raised central portion.

11. The solder pad interface of claim 7, wherein the solder pad comprises the raised central portion provides the non-soldermask defined interface between the solder pad and the solder joint.

12. The solder pad interface of claim 11, wherein the raised central portion comprises a top and sides of the non-soldermask defined interface, and wherein the solder joint comprises a bond to the top and sides of the non-soldermask defined interface.

13. The solder pad interface of claim 7, wherein the substrate is an integrated circuit chip.

14. The solder pad interface of claim 7, wherein the substrate is a printed circuit board.

15. A solder pad on a substrate, the solder pad comprising:
a raised central portion with sides and a top; and
an unraised peripheral portion having an edge; and
a soldermask;
wherein:
the soldermask covers the edge of the peripheral portion to provide a soldermask defined interface between the solder pad and the substrate; and
the sides and the top of the raised central portion provide a non-soldermask defined interface for attachment of a solder joint.

16. The solder pad of claim 15, wherein the solder pad is substantially circular.

17. The solder pad of claim 15, wherein the non-soldermask defined interface comprises a gap between the raised central portion and the soldermask.

18. A printed circuit board comprising the solder pad of claim 15

19. An electronic device comprising the printed circuit board of claim 18.

20. An integrated circuit chip comprising the solder pad of claim 15.
